(19) United States
(12) Patent Application Publication
(10) Pub. No.: US 2021/0278581 A1
(43) Pub. Date: Sep. 9, 2021

(54) POLARIZING PLATE WITH OPTICAL COMPENSATION LAYER AND ORGANIC EL PANEL USING SAME

(71) Applicant: NITTO DENKO CORPORATION, Ibaraki-shi, Osaka (JP)

(72) Inventors: Ayaka Umemoto, Ibaraki-shi (JP); Takeharu Kitagawa, Ibaraki-shi (JP); Yuki Hasegawa, Ibaraki-shi (JP)

(73) Assignee: NITTO DENKO CORPORATION, Ibaraki-shi, Osaka (JP)

(21) Appl. No.: 16/476,605

(22) PCT Filed: Dec. 12, 2017
(86) PCT No.: PCT/JP2017/044535

§ 371 Date: Jul. 9, 2019

(30) Foreign Application Priority Data
Jan. 18, 2017 (JP) 2017-006469

(51) Int. Cl. G02B 5/30; H01L 51/52

(52) U.S. Cl. CPC G02B 5/3016; H01L 2251/5338; H01L 51/5293

(57) ABSTRACT

There is provided an extremely thin polarizing plate with optical compensation layers which has an excellent antireflection characteristic, and which is suppressed in adverse effect on the display performance of an image display apparatus resulting from a foreign material. A polarizing plate with optical compensation layers of the present invention includes in this order: a polarizer; a first optical compensation layer; and a second optical compensation layer. The first optical compensation layer shows a refractive index characteristic of nx=nz>ny, and has an in-plane retardation Re(550) of from 220 nm to 320 nm. The second optical compensation layer shows a refractive index characteristic of nx>ny=nz, and has an in-plane retardation Re(550) of from 100 nm to 200 nm. The first optical compensation layer contains foreign materials, the first optical compensation layer has a thickness of 1.5 μm or more, and the first optical compensation layer has a substantially flat surface.

### TECHNICAL FIELD

The present invention relates to a polarizing plate with optical compensation layers and an organic EL panel using the same.

### BACKGROUND ART

In recent years, along with widespread use of thin displays, a display having an organic EL panel mounted thereon (organic EL display apparatus) has been proposed. The organic EL panel has a metal layer having high reflectivity, and hence is liable to cause a problem of, for example, reflection of ambient light or reflection of a background. A circularly polarizing plate obtained by laminating a polarizer, and a λ/2 plate and a λ/4 plate each including a resin film has been known as a general circularly polarizing plate.

In recent years, there has been a growing demand for making the organic EL display apparatus flexible and bendable. In order to cope with such demand, the thinning of a circularly polarizing plate has been strongly desired, and hence a circularly polarizing plate in which a λ/2 plate and a λ/4 plate each include an applied layer of a liquid crystal compound has been proposed. In such circularly polarizing plate, however, there may occur a problem in that a foreign material that may be included in its production process (the foreign material has not been a problem in each of the λ/2 plate and the λ/4 plate each including the resin film) serves as a luminescent point to adversely affect its display characteristics and to reduce its production yield.

### CITATION LIST

### Patent Literature

[PTL 1] JP 5745686 B2
[PTL 2] JP 2014-089431 A1
[PTL 3] JP 2006-133652 A1
[PTL 4] JP 2014-134775 A1
[PTL 5] JP 2014-074817 A1
[PTL 6] JP 2003-207644 A1
[PTL 7] JP 2004-271695 A1

### SUMMARY OF INVENTION

### Technical Problem

The present invention has been made to solve the above-mentioned problem, and a primary object of the present invention is to provide a polarizing plate with optical compensation layers that is extremely thin, that has an excellent antireflection characteristic, and that is suppressed in adverse effect on the display performance of an image display apparatus resulting from a foreign material.

### Solution to Problem

A polarizing plate with optical compensation layers according to an embodiment of the present invention includes in this order: a polarizer; a first optical compensation layer; and a second optical compensation layer. The first optical compensation layer shows a refractive index characteristic of nx=nz>ny, and has an in-plane retardation Re (550) of from 220 nm to 320 nm. The second optical compensation layer shows a refractive index characteristic of nx>ny=nz, and has an in-plane retardation Re(550) of from 100 nm to 200 nm. The first optical compensation layer contains foreign materials, the first optical compensation layer has a thickness of 1.5 μm or more, and the first optical compensation layer has a substantially flat surface.

In one embodiment of the present invention, the foreign materials include rubbing debris. In one embodiment of the present invention, the foreign materials have an average particle diameter of 1.3 μm or less.

In one embodiment of the present invention, an angle formed by an absorption axis of the polarizer and a slow axis of the first optical compensation layer is from 10° to 20°, and an angle formed by the absorption axis of the polarizer and a slow axis of the second optical compensation layer is from 70° to 80°.

In one embodiment of the present invention, the first optical compensation layer and the second optical compensation layer each include an alignment fixed layer of a liquid crystal compound.

According to another aspect of the present invention, an image display apparatus is provided. The image display apparatus includes the polarizing plate with optical compensation layers as described above.

In one embodiment of the present invention, the image display apparatus includes a flexible organic electroluminescence display apparatus.

### Advantageous Effects of Invention

According to the present invention, the polarizing plate with optical compensation layers that is extremely thin, that has an excellent antireflection characteristic, and that is suppressed in adverse effect on the display performance of an image display apparatus resulting from a foreign material can be obtained by: using the negative A-plate serving as an alignment fixed layer of a liquid crystal compound as a λ/2 plate; using the positive A-plate serving as an alignment fixed layer of a liquid crystal compound as a λ/4 plate; and arranging the plates on the polarizer in the stated order.

### BRIEF DESCRIPTION OF DRAWINGS

FIG. 1 is a schematic sectional view of a polarizing plate with optical compensation layers according to one embodiment of the present invention.

### DESCRIPTION OF EMBODIMENTS

Preferred embodiments of the present invention are described below. However, the present invention is not limited to these embodiments.

### Definitions of Terms and Symbols

The definitions of terms and symbols used herein are as described below.

### (1) Refractive Indices (nx, ny, and nz)

“nx” represents a refractive index in a direction in which an in-plane refractive index is maximum (that is, slow axis direction), “ny” represents a refractive index in a direction perpendicular to the slow axis in the plane (that is, fast axis direction), and “nz” represents a refractive index in a thickness direction.

### (2) In-Plane Retardation (Re)

“Re(λ)” refers to an in-plane retardation measured at 23° C. with light having a wavelength of λ nm. For example, “Re (550)” refers to an in-plane retardation measured at 23° C. with light having a wavelength of 550 nm. The Re(λ) is determined from the equation “Re(λ)=(nx−ny)×d” when the thickness of a layer (film) is represented by d (nm).

### (3) Thickness Direction Retardation (Rth)

“Rth(λ)” refers to a thickness direction retardation measured at 23° C. with light having a wavelength of λ nm. For example, “Rth(550)” refers to a thickness direction retardation measured at 23° C. with light having a wavelength of 550 nm. The Rth(λ) is determined from the equation “Rth(λ)=(nx−nz)×d” when the thickness of a layer (film) is represented by d (nm).

### (4) Nz Coefficient

An Nz coefficient is determined from the equation “Nz=Rth/Re”.

### (5) Substantially Perpendicular or Parallel

The expressions “substantially perpendicular” and “approximately perpendicular” include a case in which an angle formed by two directions is 90°±10°, and the angle is preferably 90°±7°, more preferably 90°±5°. The expressions “substantially parallel” and “approximately parallel” include a case in which an angle formed by two directions is 0°±10°, and the angle is preferably 0°±7°, more preferably 0°±5°. Moreover, the simple expression “perpendicular” or “parallel” as used herein may include a substantially perpendicular state or a substantially parallel state.

### (6) Alignment Fixed Layer

The term “alignment fixed layer” refers to such a layer that a liquid crystal compound is aligned in the layer in a predetermined direction and its alignment state is fixed. The term “alignment fixed layer” is a concept encompassing an alignment cured layer obtained by curing a liquid crystal monomer.

### (7) Angle

When reference is made to an angle in the present specification, the angle encompasses angles in both of a clockwise direction and a counterclockwise direction unless otherwise stated.

A. Overall Configuration of Polarizing Plate with Optical Compensation Layers

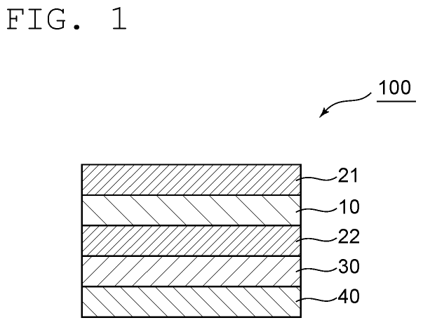

FIG. 1 is a schematic sectional view of a polarizing plate with optical compensation layers according to one embodiment of the present invention. For ease of viewing, in the FIGURE, a ratio between the thicknesses of the respective layers and the respective optical films constituting the polarizing plate with optical compensation layers is different from an actual ratio. A polarizing plate 100 with optical compensation layers of this embodiment includes a polarizer 10, a first protective layer 21 arranged on one side of the polarizer 10, a second protective layer 22 arranged on the other side of the polarizer 10, and a first optical compensation layer 30 and a second optical compensation layer 40 sequentially arranged on the side of the second protective layer 22 opposite to the polarizer 10. That is, the polarizing plate 100 with optical compensation layers includes the polarizer 10, the first optical compensation layer 30, and the second optical compensation layer 40 in the stated order. At least one of the first protective layer 21 or the second protective layer 22 may be omitted in accordance with purposes and the configuration of an image display apparatus to which the polarizing plate with optical compensation layers is applied.

An angle formed by the absorption axis of the polarizer 10 and the slow axis of the first optical compensation layer 30 is typically from 10° to 20°. An angle formed by the absorption axis of the polarizer 10 and the slow axis of the second optical compensation layer 40 is typically from 70° to 80°. An angle formed by the slow axis of the first optical compensation layer 30 and the slow axis of the second optical compensation layer 40 is typically from 55° to 65°. With such configuration, an extremely excellent circular polarization characteristic is achieved over a wide wavelength band, and as a result, an extremely excellent antireflection characteristic can be achieved.

The first optical compensation layer 30 shows a refractive index characteristic of nx=nz>ny. Further, the in-plane retardation Re(550) of the first optical compensation layer 30 is from 220 nm to 320 nm. That is, the first optical compensation layer 30 is a so-called negative A-plate, and may function as a λ/2 plate. The second optical compensation layer 40 shows a refractive index characteristic of nx>ny=nz. Further, the in-plane retardation Re(550) of the second optical compensation layer 40 is from 100 nm to 200 nm. That is, the second optical compensation layer 40 is a so-called positive A-plate, and may function as a λ/4 plate. The first optical compensation layer 30 and the second optical compensation layer 40 are each typically an alignment fixed layer of a liquid crystal compound (hereinafter sometimes referred to as “liquid crystal alignment fixed layer”). The use of the liquid crystal compound can make a difference between the nx and ny of an optical compensation layer much larger than that in the case where a non-liquid crystal material is used, and hence can significantly reduce the thickness of the optical compensation layer for obtaining a desired in-plane retardation. As a result, a significant thinning of the polarizing plate with optical compensation layers (ultimately, an organic EL display apparatus) can be achieved.

In the embodiment of the present invention, when the negative A-plate serving as a liquid crystal alignment fixed layer is used as a λ/2 plate, the positive A-plate serving as a liquid crystal alignment fixed layer is used as a λ/4 plate, and the plates are arranged on the polarizer in the above-mentioned order, a significant thinning of the polarizing plate with optical compensation layers can be achieved, an extremely excellent circular polarization characteristic can be achieved over a wide wavelength band, and a display defect due to a foreign material (described later) that may be inevitably included in a production process for the polarizing plate with optical compensation layers can be significantly suppressed. The term “display defect due to a foreign material” typically means that, when the polarizing plate with optical compensation layers is applied to an image display apparatus, the foreign material and a peripheral portion thereof serve as luminescent points. In the polarizing plate with optical compensation layers according to the embodiment of the present invention, such display defect is suppressed, and hence an adverse effect on the display performance of the image display apparatus resulting from the foreign material can be prevented. In addition, the polarizing plate with optical compensation layers is extremely excellent in production yield. Such display defect is a problem that has newly occurred in a mode in which an optical compensation layer includes an extremely thin liquid crystal alignment fixed layer, and one feature of the present invention lies in that the present invention has solved such new problem. As a result, according to the present invention, a significant thinning of the polarizing plate with optical compensation layers can be achieved.

In the embodiment of the present invention, the first optical compensation layer 30 contains foreign materials. The foreign materials are foreign materials that may be inevitably included in the production process, and are, for example, foreign materials caused by the alignment treatment of the liquid crystal compound, more specifically, foreign materials caused by rubbing treatment (rubbing debris). When an optical compensation layer includes a resin film, such foreign materials are originally absent, and even if the foreign materials are present, it is assumed that the thickness of the resin film prevents the foreign materials from leading to display defects. As described above, one feature of the present invention lies in that the adverse effect of a foreign material that may be a problem in a mode in which an optical compensation layer includes an extremely thin liquid crystal alignment fixed layer is prevented. Specifically, the number of foreign materials actually present in the first optical compensation layer may be 100 foreign materials/m² or more in one embodiment, and may be from about 150 foreign materials/m² to about 300 foreign materials/m² in another embodiment. The average particle diameter of the foreign materials is typically 1.3 μm or less, preferably from 0.1 μm to 1.0 μm. Meanwhile, the number of display defects in the polarizing plate with optical compensation layers according to the embodiment of the present invention is preferably 10 display defects/m² or less, more preferably 8 display defects/m² or less. That is, according to the embodiment of the present invention, even when many foreign materials are present in the first optical compensation layer, most of such foreign materials can be prevented from being recognized as display defects. The number of the actually present foreign materials may be recognized and measured by observing the polarizing plate with optical compensation layers with, for example, an optical microscope (e.g., a differential interference microscope). The number of the display defects may be measured as follows: the display defects are recognized as luminescent points in a pseudo-crossed Nicols state obtained by arranging the polarizing plate with optical compensation layers in, for example, a differential interference microscope, and rotating a polarizing plate incorporated into the microscope, and their number is measured.

In the embodiment of the present invention, the thickness of the first optical compensation layer is 1.5 μm or more, and its surface is substantially flat. When the first optical compensation layer (negative A-plate) is used as a λ/2 plate, such thickness can be achieved. As a result, even when a foreign material is present, the surface of the first optical compensation layer can be made substantially flat. The phrase “substantially flat” as used herein means that a protruding portion having a height of 0.4 μm or more is absent.

The ratio of the thickness of the first optical compensation layer to the average particle diameter of the foreign materials is preferably 1.2 or more, more preferably from 1.5 to 2.0. When the ratio falls within such range, a flat surface can be satisfactorily achieved. As a result, display defects due to the foreign materials can be satisfactorily prevented.

The entire thickness of the polarizing plate with optical compensation layers (herein, the total thickness of the first protective layer, the polarizer, the first optical compensation layer, and the second optical compensation layer: the thickness of an adhesive layer for laminating the layers and the polarizer is not included) is preferably from 20 μm to 100 μm, more preferably from 25 μm to 70 μm. According to the embodiment of the present invention, the display defects due to the foreign materials can be satisfactorily suppressed while such significant thinning is achieved.

A conductive layer and a substrate (none of which is shown) may be arranged on the side of the second optical compensation layer 40 opposite to the first optical compensation layer 30 (i.e., outside the second optical compensation layer 40) in the stated order as required. The substrate is laminated so as to be in close contact with the conductive layer. The phrase “laminated so as to be in close contact” as used herein means that two layers are laminated directly and fixedly without an adhesion layer (e.g., an adhesive layer or a pressure-sensitive adhesive layer) being interposed. The conductive layer and the substrate may be typically introduced as a laminate of the substrate and the conductive layer into the polarizing plate 100 with optical compensation layers. When the conductive layer and the substrate are further arranged, the polarizing plate 100 with optical compensation layers may be suitably used for an inner touch panel-type input display apparatus.

The polarizing plate with optical compensation layers may be of a sheet shape, or may be of an elongate shape.

The respective layers and the respective optical films constituting the polarizing plate with optical compensation layers are described in detail below.

A-1. Polarizer

Any appropriate polarizer may be adopted as the polarizer 10. For example, a resin film forming the polarizer may be a single-layer resin film, or may be a laminate of two or more layers.

Specific examples of the polarizer including a single-layer resin film include: a polarizer obtained by subjecting a hydrophilic polymer film, such as a polyvinyl alcohol (PVA)-based film, a partially formalized PVA-based film, or an ethylene-vinyl acetate copolymer-based partially saponified film, to dyeing treatment with a dichroic substance, such as iodine or a dichroic dye, and stretching treatment; and a polyene-based alignment film, such as a dehydration-treated product of PVA or a dehydrochlorination-treated product of polyvinyl chloride. A polarizer obtained by dyeing the PVA-based film with iodine and uniaxially stretching the resultant is preferably used because the polarizer is excellent in optical characteristics.

The dyeing with iodine is performed by, for example, immersing the PVA-based film in an aqueous solution of iodine. The stretching ratio of the uniaxial stretching is preferably from 3 times to 7 times. The stretching may be performed after the dyeing treatment, or may be performed while the dyeing is performed. In addition, the dyeing may be performed after the stretching has been performed. The PVA-based film is subjected to swelling treatment, cross-linking treatment, washing treatment, drying treatment, or the like as required. For example, when the PVA-based film is immersed in water to be washed with water before the dyeing, contamination or an antiblocking agent on the surface of the PVA-based film can be washed off. In addition, the PVA-based film is swollen and hence dyeing unevenness or the like can be prevented.

The polarizer obtained by using the laminate is specifically, for example, a polarizer obtained by using a laminate of a resin substrate and a PVA-based resin layer (PVA-based resin film) laminated on the resin substrate, or a laminate of a resin substrate and a PVA-based resin layer formed on the resin substrate through application. The polarizer obtained by using the laminate of the resin substrate and the PVA-based resin layer formed on the resin substrate through application may be produced by, for example, a method involving: applying a PVA-based resin solution onto the resin substrate; drying the solution to form the PVA-based resin layer on the resin substrate, to thereby provide the laminate of the resin substrate and the PVA-based resin layer; and stretching and dyeing the laminate to turn the PVA-based resin layer into the polarizer. In this embodiment, the stretching typically includes the stretching of the laminate under a state in which the laminate is immersed in an aqueous solution of boric acid. The stretching may further include the aerial stretching of the laminate at high temperature (e.g., 95° C. or more) before the stretching in the aqueous solution of boric acid as required. The resultant laminate of the resin substrate and the polarizer may be used as it is (i.e., the resin substrate may be used as a protective layer for the polarizer). Alternatively, a product obtained as described below may be used: the resin substrate is peeled from the laminate of the resin substrate and the polarizer, and any appropriate protective layer in accordance with purposes is laminated on the peeling surface. Details about such method of producing a polarizer are described in, for example, JP 2012-73580 A. The entire description of the laid-open publication is incorporated herein by reference.

The thickness of the polarizer is preferably 25 μm or less, more preferably from 1 μm to 12 μm, still more preferably from 3 μm to 12 μm, particularly preferably from 3 μm to 8 μm. When the thickness of the polarizer falls within such range, curling at the time of heating can be satisfactorily suppressed, and satisfactory appearance durability at the time of heating is obtained.

The polarizer preferably shows absorption dichroism at any wavelength in the wavelength range of from 380 nm to 780 nm. As described above, the single layer transmittance of the polarizer is from 43.0% to 46.0%, preferably from 44.5% to 46.0%. The polarization degree of the polarizer is preferably 97.0% or more, more preferably 99.0% or more, still more preferably 99.9% or more.

A-2. First Protective Layer

The first protective layer 21 is formed of any appropriate film that may be used as a protective layer fora polarizer. Specific examples of a material serving as a main component for the film include: cellulose-based resins, such as triacetyl cellulose (TAC); and polyester-based, polyvinyl alcohol-based, polycarbonate-based, polyamide-based, polyimide-based, polyether sulfone-based, polysulfone-based, polystyrene-based, polynorbornene-based, polyolefin-based, (meth)acrylic, and acetate-based transparent resins. The examples also include (meth)acrylic, urethane-based, (meth)acrylic urethane-based, epoxy-based, and silicone-based thermosetting resins or UV-curable resins. The examples also include glassy polymers, such as a siloxane-based polymer. In addition, a polymer film described in JP 2001-343529 A (WO 01/37007 A1) may also be used. For example, a resin composition containing a thermoplastic resin having a substituted or unsubstituted imide group in a side chain thereof and a thermoplastic resin having a substituted or unsubstituted phenyl group and a nitrile group in side chains thereof may be used as a material for the film, and is, for example, a resin composition containing an alternating copolymer formed of isobutene and N-methylmaleimide, and an acrylonitrile-styrene copolymer. The polymer film may be, for example, an extruded product of the resin composition.

As described later, the polarizing plate with optical compensation layers of the present invention is typically arranged on the viewer side of an image display apparatus, and the first protective layer 21 is typically arranged on the viewer side. Therefore, the first protective layer 21 may be subjected to surface treatment, such as hard coat treatment, antireflection treatment, anti-sticking treatment, or antiglare treatment, as required. Further/alternatively, the first protective layer 21 may be subjected to treatment for improving viewability when the display screen of the image display apparatus is viewed through polarized sunglasses (typically the impartment of a circular (elliptical) polarization function or the impartment of an ultra-high retardation) as required. When any such treatment is performed, even in the case where the display screen is viewed through a polarizing lens, such as polarized sunglasses, excellent viewability can be achieved. Therefore, the polarizing plate with optical compensation layers can be suitably applied even to an image display apparatus that may be used outdoors.

Any appropriate thickness may be adopted as the thickness of the first protective layer. The thickness of the first protective layer is, for example, from 10 μm to 50 μm, preferably from 15 μm to 40 μm. When the first protective layer is subjected to surface treatment, its thickness is a thickness including the thickness of a surface-treated layer.

A-3. Second Protective Layer

The second protective layer 22 is also formed of any appropriate film that may be used as a protective layer fora polarizer. A material serving as a main component for the film is as described in the section A-2 for the first protective layer. It is preferred that the second protective layer 22 be optically isotropic. The phrase “optically isotropic” as used herein means that the layer has an in-plane retardation Re (550) of from 0 nm to 10 nm and a thickness direction retardation Rth(550) of from −10 nm to +10 nm.

The thickness of the second protective layer is, for example, from 15 μm to 35 μm, preferably from 20 μm to 30 μm. A difference between the thickness of the first protective layer and the thickness of the second protective layer is preferably 15 μm or less, more preferably 10 μm or less. When the thickness difference falls within such range, the curling of the layers at the time of their bonding can be satisfactorily suppressed. The thickness of the first protective layer and the thickness of the second protective layer may be identical to each other, the first protective layer may be thicker than the other, or the second protective layer may be thicker than the other. The first protective layer is typically thicker than the second protective layer.

A-4. First Optical Compensation Layer

As described above, the first optical compensation layer 30 shows a refractive index characteristic of nx=nz>ny. Further, as described above, the first optical compensation layer may function as a λ/2 plate. As described above, the in-plane retardation Re (550) of the first optical compensation layer is from 220 nm to 320 nm, preferably from 240 nm to 300 nm, more preferably from 250 nm to 280 nm. Herein, the equation “nx=nz” encompasses not only a case in which the nx and the nz are completely equal to each other but also a case in which the nx and the nz are substantially equal to each other. Therefore, a case in which a relationship of nx>nz or nx<nz is satisfied may occur to the extent that the effects of the present invention are not impaired. The Nz coefficient of the first optical compensation layer is, for example, from −0.1 to 0.1. When such relationship is satisfied, a more excellent reflection hue can be achieved. The thickness direction retardation Rth(550) of the first optical compensation layer may be adjusted in accordance with the in-plane retardation Re (550) so that such Nz coefficient may be obtained.

As described above, the first optical compensation layer 30 is a liquid crystal alignment fixed layer, and is more specifically a layer in which a discotic liquid crystal compound is fixed under a state of being vertically aligned. The discotic liquid crystal compound is generally a liquid crystal compound having such a disc-shaped molecular structure that a cyclic core, such as benzene, 1,3,5-triazine, or a calixarene, is arranged at the center of a molecule, and is radially substituted with, for example, a linear alkyl group or alkoxy group, or a substituted benzoyloxy group serving as a side chain thereof. Typical examples of the discotic liquid crystal compound include: a benzene derivative, a triphenylene derivative, a truxene derivative, and a phthalocyanine derivative each described in a research report by C. Destrade et al., Mol. Cryst. Liq. Cryst. Vol. 71, p. 111 (1981); a cyclohexane derivative described in a research report by B. Kohne et al., Angew. Chem. Vol. 96, p. 70 (1984); and azacrown-based and phenylacetylene-based macrocycles described in a research report by J. M. Lehn et al., J. Chem. Soc. Chem. Commun., p. 1794 (1985) and a research report by J. Zhang et al., J. Am. Chem. Soc. Vol. 116, p. 2655 (1994). Further specific examples of the discotic liquid crystal compound include compounds described in JP 2006-133652 A, JP 2007-108732 A, and JP 2010-244038 A. The descriptions of the literatures and the laid-open publications are incorporated herein by reference.

The first optical compensation layer may be formed by, for example, the following procedure. Herein, a case in which the first optical compensation layer of an elongate shape is formed on an elongate polarizer is described. First, while an elongate substrate is conveyed, an application liquid for forming an alignment film is applied onto the substrate, and is dried to form an applied film. The applied film is subjected to rubbing treatment in a predetermined direction to form an alignment film on the substrate. The predetermined direction corresponds to the slow axis direction of the first optical compensation layer to be obtained, and is at, for example, about 15° with respect to the elongate direction of the substrate. Next, an application liquid for forming the first optical compensation layer (solution containing the discotic liquid crystal compound, and as required, a cross-linkable monomer) is applied onto the formed alignment film and heated. Through the heating, the solvent of the application liquid is removed, and the alignment of the discotic liquid crystal compound is advanced. The heating may be performed in one stage, or may be performed in a plurality of stages while a temperature is changed. Next, the cross-linkable (or polymerizable) monomer is cross-linked (or polymerized) by UV irradiation to fix the alignment of the discotic liquid crystal compound. Thus, the first optical compensation layer is formed on the substrate. Finally, the first optical compensation layer is bonded to the polarizer via an adhesive layer, and the substrate is peeled (i.e., the first optical compensation layer is transferred from the substrate onto the polarizer). Thus, the first optical compensation layer may be laminated on the polarizer. A method of vertically aligning the discotic liquid crystal compound is described in, for example, [0153] of JP 2006-133652 A. The description of the laid-open publication is incorporated herein by reference.

As described above, the thickness of the first optical compensation layer is 1.5 μm or more, preferably from 1.6 μm to 2.0 μm. As described above, with such thickness, even when a foreign material is present, the surface of the first optical compensation layer can be made substantially flat.

A-5. Second Optical Compensation Layer

As described above, the second optical compensation layer 40 shows a refractive index characteristic of nx>ny=nz. Further, as described above, the second optical compensation layer may function as a λ/4 plate. The in-plane retardation Re(550) of the second optical compensation layer is typically from 100 nm to 200 nm, preferably from 110 nm to 180 nm, more preferably from 120 nm to 160 nm. Herein, the equation “ny=nz” encompasses not only a case in which the ny and the nz are completely equal to each other but also a case in which the ny and the nz are substantially equal to each other. Therefore, a case in which a relationship of ny>nz or ny<nz is satisfied may occur to the extent that the effects of the present invention are not impaired. The Nz coefficient of the second optical compensation layer is, for example, from 0.9 to 1.3. The thickness direction retardation Rth(550) of the second optical compensation layer may be adjusted in accordance with the in-plane retardation Re(550) so that such Nz coefficient may be obtained.

In the second optical compensation layer, the molecules of a rod-shaped liquid crystal compound are typically aligned under a state of being arrayed in the slow axis direction of the second optical compensation layer (homogeneous alignment). The liquid crystal compound is, for example, a liquid crystal compound whose liquid crystal phase is a nematic phase (nematic liquid crystal). For example, a liquid crystal polymer or a liquid crystal monomer may be used as such liquid crystal compound. The expression mechanism of the liquid crystallinity of the liquid crystal compound may be lyotropic or thermotropic. The liquid crystal polymer and the liquid crystal monomer may be used alone or in combination thereof.

When the liquid crystal compound is a liquid crystal monomer, the liquid crystal monomer is preferably a polymerizable monomer or a cross-linkable monomer. This is because the polymerization or cross-linking of the liquid crystal monomer can fix the alignment state of the liquid crystal monomer. After the liquid crystal monomer has been aligned, when the molecules of the liquid crystal monomer are, for example, polymerized or cross-linked, the alignment state can be fixed by the polymerization or the cross-linking. Herein, a polymer is formed by the polymerization, and a three-dimensional network structure is formed by the cross-linking. The polymer and the structure are non-liquid crystalline. Therefore, the second optical compensation layer thus formed does not undergo, for example, a transition to a liquid crystal phase, a glass phase, or a crystal phase due to a temperature change, which is peculiar to a liquid crystalline compound. As a result, the second optical compensation layer serves as a retardation layer that is not affected by any temperature change, that is, is extremely excellent in stability.

A temperature range in which the liquid crystal monomer shows liquid crystallinity varies depending on its kind. Specifically, the temperature range is preferably from 40° C. to 120° C., more preferably from 50° C. to 100° C., most preferably from 60° C. to 90° C.

Any appropriate liquid crystal monomer may be adopted as the liquid crystal monomer. For example, a polymerizable mesogenic compound and the like described in JP 2002-533742 A (WO 00/37585 A1), EP 358208 B1 (U.S. Pat. No. 5,211,877 B), EP 66137 B1 (U.S. Pat. No. 4,388,453 B), WO 93/22397 A1, EP 0261712 A1, DE 19504224 A1, DE 4408171 A1, GB 2280445 B, and the like may be used. Specific examples of such polymerizable mesogenic compound include a product available under the product name LC242 from BASF SE, a product available under the product name E7 from Merck KGaA, and a product available under the product name LC-Sillicon-CC3767 from Wacker Chemie AG. The liquid crystal monomer is preferably, for example, a nematic liquid crystal monomer. Further specific examples of the liquid crystal compound are described in JP 2006-163343 A and JP 2004-271695 A. The descriptions of the laid-open publications are incorporated herein by reference.

The second optical compensation layer may be formed by: subjecting the surface of a predetermined substrate to alignment treatment; applying an application liquid containing the liquid crystal compound to the surface; aligning the liquid crystal compound in a direction corresponding to the alignment treatment; and fixing the alignment state. In one embodiment, the substrate is any appropriate resin film, and the second optical compensation layer formed on the substrate may be transferred onto the surface of the first optical compensation layer via an adhesive layer.

Any appropriate alignment treatment may be adopted as the alignment treatment. Specific examples thereof include mechanical alignment treatment, physical alignment treatment, and chemical alignment treatment. Specific examples of the mechanical alignment treatment include rubbing treatment and stretching treatment. Specific examples of the physical alignment treatment include magnetic field alignment treatment and electric field alignment treatment. Specific examples of the chemical alignment treatment include an oblique deposition method and optical alignment treatment. Any appropriate conditions may be adopted as treatment conditions for the various kinds of alignment treatment in accordance with purposes. In the embodiment of the present invention, the optical alignment treatment is preferred. This is because the optical alignment treatment does not cause a foreign material, such as rubbing debris. When a λ/4 plate having a small thickness is formed by the optical alignment treatment, a display defect due to a foreign material can be suppressed. The details of a method of forming an alignment fixed layer through the optical alignment treatment are described in, for example, JP 2004-271695 A described above.

The alignment of the liquid crystal compound is performed by treating the liquid crystal compound at the temperature at which the liquid crystal compound shows a liquid crystal phase in accordance with the kind of the liquid crystal compound. When the liquid crystal compound is treated at such temperature, the liquid crystal compound is brought into a liquid crystal state, and hence the liquid crystal compound is aligned in accordance with the direction of the alignment treatment of the surface of the substrate.

In one embodiment, the fixation of the alignment state is performed by cooling the liquid crystal compound aligned as described above. When the liquid crystal compound is a polymerizable monomer or a cross-linkable monomer, the fixation of the alignment state is performed by subjecting the liquid crystal compound aligned as described above to polymerization treatment or cross-linking treatment.

The thickness of the second optical compensation layer is preferably from 0.5 μm to 1.2 μm. With such thickness, the layer may appropriately function as a λ/4 plate.

A-6. Conductive Layer or Conductive Layer with Substrate

The conductive layer may be formed by forming a metallic oxide film on any appropriate substrate through any appropriate film forming method (e.g., a vacuum vapor deposition method, a sputtering method, a CVD method, an ion plating method, and a spraying method). After the film formation, heating treatment (e.g., at from 100° C. to 200° C.) may be performed as required. When the heating treatment is performed, an amorphous film can be crystallized. Examples of the metal oxide include indium oxide, tin oxide, zinc oxide, indium-tin composite oxide, tin-antimony composite oxide, zinc-aluminum composite oxide, and indium-zinc composite oxide. An indium oxide may be doped with a divalent metal ion or a tetravalent metal ion. The metal oxide is preferably an indium-based composite oxide, more preferably indium-tin composite oxide (ITO). The indium-based composite oxide has features of having a high transmittance (e.g., 80% or more) in a visible light region (380 nm to 780 nm) and having a low surface resistance value per unit area.

When the conductive layer contains the metal oxide, the thickness of the conductive layer is preferably 50 nm or less, more preferably 35 nm or less. The lower limit of the thickness of the conductive layer is preferably 10 nm.

The surface resistance value of the conductive layer is preferably 300 ohms per square (Ω/□) or less, more preferably 150Ω/□ or less, still more preferably 100Ω/□ or less.

The conductive layer may be preferably formed as an electrode through the patterning of the metal oxide film by an etching method or the like. The electrode may function as a touch sensor electrode configured to sense contact with a touch panel.

The conductive layer may be transferred from the substrate onto the second optical compensation layer to serve alone as a layer constituting the polarizing plate with optical compensation layers, or may be laminated as a laminate with the substrate (a conductive layer with a substrate, i.e., a conductive film or a sensor film) on the second optical compensation layer. Typically, as described above, the conductive layer and the substrate may be introduced as a conductive layer with a substrate into the polarizing plate with optical compensation layers.

Any appropriate resin is given as a material forming the substrate. The resin is preferably a resin excellent in transparency. Specific examples thereof include a cyclic olefin-based resin, a polycarbonate-based resin, a cellulose-based resin, a polyester-based resin, and an acrylic resin.

It is preferred that the substrate be optically isotropic. Therefore, the conductive layer can be used as a conductive layer with an isotropic substrate in the polarizing plate with optical compensation layers. A material forming the substrate that is optically isotropic (isotropic substrate) is, for example, a material using a resin free of any conjugated system, such as a norbornene-based resin or an olefin-based resin, as a main skeleton, or a material having a cyclic structure, such as a lactone ring or a glutarimide ring, in the main chain of an acrylic resin. The use of any such material can suppress the expression of a retardation in association with the orientation of the molecular chain of the material at the time of the formation of the isotropic substrate to a low level.

The substrate has a thickness of preferably from 10 μm to 200 μm, more preferably from 20 μm to 60 μm.

A-7. Others

Any appropriate adhesive (adhesive layer) is used in the lamination of the respective layers constituting the polarizing plate with optical compensation layers of the present invention. An aqueous adhesive (e.g., a PVA-based adhesive) may be typically used in the lamination of the polarizer and each of the protective layers. An active energy ray (e.g., UV)-curable adhesive is typically used in the lamination of the optical compensation layers. The thickness of the adhesive layer is preferably from 0.01 μm to 7 μm, more preferably from 0.01 μm to 5 μm, still more preferably from 0.01 μm to 2 μm.

Although not shown, a pressure-sensitive adhesive layer may be arranged on the second optical compensation layer 40 side (when the conductive layer and the substrate are arranged, the substrate side) of the polarizing plate 100 with optical compensation layers. When the pressure-sensitive adhesive layer is arranged in advance, the polarizing plate with optical compensation layers can be easily bonded to any other optical member (e.g., an image display cell). Practically, a separator is temporarily bonded to the pressure-sensitive adhesive layer in a peelable manner to protect the pressure-sensitive adhesive layer until its actual use and to enable roll formation.

B. Image Display Apparatus

An image display apparatus of the present invention includes the polarizing plate with optical compensation layers described in the section A. The image display apparatus typically includes the polarizing plate with optical compensation layers on its viewer side. Typical examples of the image display apparatus include a liquid crystal display apparatus and an organic electroluminescence (EL) display apparatus. In one embodiment, the image display apparatus is a flexible organic EL display apparatus. In the flexible organic EL display apparatus, an effect of the thinning of the polarizing plate with optical compensation layers can be significantly exhibited.

### EXAMPLES

Now, the present invention is specifically described byway of Examples. However, the present invention is not limited by these Examples. Measurement methods for characteristics are as described below.

(1) Thickness

Measurement was performed with a dial gauge (manufactured by PEACOCK, product name: “DG-205”, dial gauge stand (product name: “pds-2”)).

(2) Retardation Value

A sample measuring 50 mm by 50 mm was cut out of each optical compensation layer to provide a measurement sample, and its retardation values were measured with AxoScan manufactured by Axometrics, Inc. A measurement wavelength was 550 nm, and a measurement temperature was 23° C.

(3) Number of Actually Present Foreign Materials

A polarizing plate with optical compensation layers obtained in each of Example and Comparative Example was observed with a differential interference microscope (OLYMPUS LG-PS2) at a magnification of 50. The number of recognized foreign materials was measured, and was converted into a number per 1 m².

(4) Number of Display Defects

Luminescent points were observed with a differential interference microscope (OLYMPUS LG-PS2) at a magnification of 50. Specifically, the observation was performed in a pseudo-crossed Nicols state obtained by arranging the polarizing plate with optical compensation layers obtained in each of Example and Comparative Example in the microscope, and rotating a polarizing plate incorporated into the microscope. The number of observed luminescent points was defined as the number of display defects, and was converted into a number per 1 m².

(5) Reflection Hue

An obtained organic EL display apparatus was caused to display a black image, and its reflection hue was measured with a viewing angle-measuring and evaluating apparatus “ConoScope” manufactured by Autronic-MELCHERS GmbH.

### Example 1

### 1-1. Production of Polarizing Plate

An amorphous polyethylene terephthalate (A-PET) film (manufactured by Mitsubishi Plastics, Inc., product name: NOVACLEAR SH046, thickness: 200 μm) was prepared as a substrate, and its surface was subjected to corona treatment (58 W/m²/min). Meanwhile, PVA (polymerization degree: 4,200, saponification degree: 99.2%) having added thereto 1 wt % of acetoacetyl-modified PVA (manufactured by The Nippon Synthetic Chemical Industry Co., Ltd., product name: GOHSEFIMER Z-200, polymerization degree: 1,200, saponification degree: 99.0% or more, acetoacetyl modification degree: 4.6%) was prepared, and was applied to the substrate so that its thickness after drying became 12 μm. The applied PVA was dried under an atmosphere at 60° C. by hot-air drying for 10 minutes. Thus, a laminate in which a PVA-based resin layer was arranged on the substrate was produced. Next, the laminate was stretched in air at 130° C. and at 2.0 times to provide a stretched laminate. Next, a step of insolubilizing the PVA-based resin layer in the stretched laminate in which PVA molecules were aligned was performed by immersing the stretched laminate in an insolubilizing aqueous solution of boric acid having a liquid temperature of 30° C. for 30 seconds. The boric acid content of the insolubilizing aqueous solution of boric acid in this step was set to 3 wt % with respect to 100 wt % of water. The stretched laminate was dyed to produce a colored laminate. The colored laminate was obtained by immersing the stretched laminate in a dyeing liquid containing iodine and potassium iodide, the liquid having a liquid temperature of 30° C., to cause the PVA-based resin layer in the stretched laminate to adsorb iodine. An iodine concentration and an immersion time were adjusted so that the single layer transmittance of a polarizer to be obtained became 44.5%. Specifically, water was used as the solvent of the dyeing liquid, its iodine concentration was set within the range of from 0.08 wt % to 0.25 wt %, and its potassium iodide concentration was set within the range of from 0.56 wt % to 1.75 wt %. A ratio between the iodine concentration and the potassium iodide concentration was 1:7. Next, a step of subjecting the PVA molecules of the PVA-based resin layer caused to adsorb iodine to cross-linking treatment was performed by immersing the colored laminate in a cross-linking aqueous solution of boric acid at 30° C. for 60 seconds. The boric acid content of the cross-linking aqueous solution of boric acid in this step was set to 3 wt % with respect to 100 wt % of water, and the potassium iodide content thereof was set to 3 wt % with respect to 100 wt % of water. Further, the resultant colored laminate was stretched in an aqueous solution of boric acid at a stretching temperature of 70° C. in the same direction as that of the stretching in air at 2.7 times so that the final stretching ratio became 5.4 times. Thus, a laminate having the configuration “substrate/polarizer” was obtained. The thickness of the polarizer was 5 μm. The boric acid content of the aqueous solution of boric acid in this step was set to 6.5 wt % with respect to 100 wt % of water, and the potassium iodide content thereof was set to 5 wt % with respect to 100 wt % of water. The resultant laminate was taken out from the aqueous solution of boric acid, and boric acid adhering to the surface of the polarizer was washed off with an aqueous solution whose potassium iodide content was set to 2 wt % with respect to 100 wt % of water. The washed laminate was dried with warm air at 60° C.

An acrylic film having a thickness of 40 μm was bonded to the surface of the polarizer of the laminate having the configuration “substrate/polarizer” obtained in the foregoing via a PVA-based adhesive. Thus, a polarizing plate having the configuration “protective layer/polarizer/resin substrate” was obtained.

### 1-2. Production of Liquid Crystal Alignment Fixed Layer Forming First Optical Compensation Layer

A liquid crystal alignment fixed layer (first optical compensation layer) was formed on a substrate (TAC film) inconformity with a procedure described in [0151] to [0156] of JP 2006-133652 A. The direction of the rubbing treatment of the layer was set to a direction at 15° in a counterclockwise direction when viewed from a viewer side with respect to the absorption axis direction of the polarizer at the time of the bonding of the layer to the polarizer. The first optical compensation layer had a thickness of 1.7 μm and an in-plane retardation Re (550) of 270 nm. Further, the first optical compensation layer was a negative A-plate showing a refractive index characteristic of nx=nz>ny. In addition, a protruding portion having a height of 0.4 μm or more was not observed on the surface of the first optical compensation layer (negative A-plate).

### 1-3. Production of Liquid Crystal Alignment Fixed Layer Forming Second Optical Compensation Layer

Ten grams of a polymerizable liquid crystal compound showing a nematic liquid crystal phase (manufactured by BASF SE: product name: “Paliocolor LC242”, represented by the below-indicated formula) and 3 g of a photopolymerization initiator for the polymerizable liquid crystal compound (manufactured by BASF SE: product name: “IRGACURE 907”) were dissolved in 40 g of toluene to prepare a liquid crystal composition (application liquid).

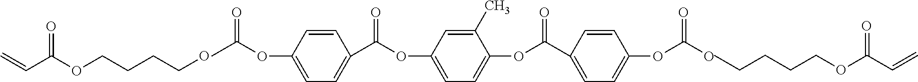

An optical alignment film was applied to the surface of a polyethylene terephthalate (PET) film (thickness: 38 μm) to subject the surface to optical alignment treatment. The direction of the optical alignment treatment was set to a direction at 75° in the counterclockwise direction when viewed from the viewer side with respect to the absorption axis direction of the polarizer at the time of the bonding of a second optical compensation layer to be obtained to the polarizer. The liquid crystal application liquid was applied to the optical alignment-treated surface with a bar coater, and was dried by heating at 90° C. for 2 minutes so that the liquid crystal compound was aligned. Light having a light quantity of 1 mJ/cm² was applied to a liquid crystal layer thus formed with a metal halide lamp to cure the liquid crystal layer. Thus, a liquid crystal alignment fixed layer (second optical compensation layer) was formed on the substrate (PET film). The second optical compensation layer had a thickness of 1.2 μm and an in-plane retardation Re(550) of 140 nm. Further, the second optical compensation layer was a positive A-plate showing a refractive index characteristic of nx>ny=nz.

1-4. Production of Polarizing Plate with Optical Compensation Layers

The A-PET film serving as the substrate was peeled from the polarizing plate obtained in the foregoing, and the first optical compensation layer was transferred from the laminate having the configuration “substrate/first optical compensation layer” onto the peeled surface via a UV-curable adhesive. Further, the second optical compensation layer was transferred from the laminate having the configuration “substrate/second optical compensation layer” onto the surface of the first optical compensation layer via a UV-curable adhesive. Thus, a polarizing plate with optical compensation layers having the configuration “protective layer/polarizer/first optical compensation layer (negative A-plate: λ/2 plate)/second optical compensation layer (positive A-plate: λ/4 plate)” was obtained.

### 1-5. Production of Organic EL Display Apparatus

A pressure-sensitive adhesive layer was formed of an acrylic pressure-sensitive adhesive on the second optical compensation layer side of the resultant polarizing plate with optical compensation layers, and was cut into dimensions measuring 50 mm by 50 mm.

A smartphone (Galaxy-S5) manufactured by Samsung Electronics Co., Ltd. was dismantled, and its organic EL display apparatus was removed. A polarizing film bonded to the organic EL display apparatus was peeled off, and the polarizing plate with optical compensation layers cut out in the foregoing was bonded instead to the remainder. Thus, an organic EL display apparatus was obtained.

### 1-6. Evaluation

The resultant polarizing plate with optical compensation layers was subjected to the evaluations (3) and (4). As a result, the number of foreign materials actually present in the first optical compensation layer (negative A-plate) was about 200 foreign materials/m², and the number of display defects in the polarizing plate with optical compensation layers was 8 display defects/m². Further, the reflection hue of the resultant organic EL display apparatus was measured by the procedure described in the (5). As a result, it was confirmed that a neutral reflection hue was achieved in each of the front direction and oblique direction of the apparatus.

### Comparative Example 1

A polarizing plate with optical compensation layers was produced in the same manner as in Example 1 except that: a positive A-plate was used as a λ/2 plate (first optical compensation layer); and a negative A-plate was used as a λ/4 plate (second optical compensation layer). A method for the production is specifically as described below.

The negative A-plate was produced in the same manner as in 1-2 of Example 1 except that: its thickness was set to 1.0 μm; and the direction of its rubbing treatment was set to a direction at 75° in the counterclockwise direction when viewed from the viewer side with respect to the absorption axis direction of the polarizer. The plate was used as the second optical compensation layer. The second optical compensation layer had an in-plane retardation Re(550) of 140 nm. Further, the positive A-plate was produced in the same manner as in 1-3 of Example 1 except that: its thickness was set to 1.7 μm; and the direction of its rubbing treatment was set to a direction at 15° in the counterclockwise direction when viewed from the viewer side with respect to the absorption axis direction of the polarizer. The plate was used as the first optical compensation layer. The first optical compensation layer had an in-plane retardation Re(550) of 270 nm. A polarizing plate with optical compensation layers having the configuration “protective layer/polarizer/first optical compensation layer (positive A-plate: λ/2 plate)/second optical compensation layer (negative A-plate: λ/4 plate)” was obtained in the same manner as in Example 1 except that those optical compensation layers were used. Further, an organic EL display apparatus was produced in the same manner as in Example 1 except that the polarizing plate with optical compensation layers was used. Many protruding portions each having a height of 0.4 μm or more were observed on the surface of the second optical compensation layer (negative A-plate).

The polarizing plate with optical compensation layers and the organic EL display apparatus thus obtained were subjected to the same evaluations as those of Example 1. As a result, the number of foreign materials actually present in the second optical compensation layer (negative A-plate) was about 200 foreign materials/m², and the number of display defects in the polarizing plate with optical compensation layers was about 160 display defects/m². With regard to a reflection hue, it was confirmed that a neutral reflection hue was achieved in each of the front direction and oblique direction of the apparatus.

### INDUSTRIAL APPLICABILITY

The polarizing plate with optical compensation layers of the present invention is suitably used for an organic EL display apparatus, and may be particularly suitably used for a flexible organic EL display apparatus.

### REFERENCE SIGNS LIST

10 polarizer
30 first optical compensation layer
40 second optical compensation layer
100 polarizing plate with optical compensation layers

1. A polarizing plate with optical compensation layers comprising in this order:
a polarizer;
a first optical compensation layer; and
a second optical compensation layer,
wherein the first optical compensation layer shows a refractive index characteristic of nx=nz>ny, and has an in-plane retardation Re(550) of from 220 nm to 320 nm,
wherein the second optical compensation layer shows a refractive index characteristic of nx>ny=nz, and has an in-plane retardation Re(550) of from 100 nm to 200 nm, and
wherein the first optical compensation layer contains foreign materials, the first optical compensation layer has a thickness of 1.5 μm or more, and the first optical compensation layer has a substantially flat surface.

2. The polarizing plate with optical compensation layers according to claim 1, wherein the foreign materials comprise rubbing debris.

3. The polarizing plate with optical compensation layers according to claim 1, wherein the foreign materials have an average particle diameter of 1.3 μm or less.

4. The polarizing plate with optical compensation layers according to claim 1, wherein an angle formed by an absorption axis of the polarizer and a slow axis of the first optical compensation layer is from 10° to 20°, and an angle formed by the absorption axis of the polarizer and a slow axis of the second optical compensation layer is from 70° to 80°.

5. The polarizing plate with optical compensation layers according to claim 1, wherein the first optical compensation layer and the second optical compensation layer each comprise an alignment fixed layer of a liquid crystal compound.

6. An image display apparatus, comprising the polarizing plate with optical compensation layers of claim 1.

7. The image display apparatus according to claim 6, wherein the image display apparatus comprises a flexible organic electroluminescence display apparatus.

8. The polarizing plate with optical compensation layers according to claim 2, wherein the first optical compensation layer has been subjected to rubbing treatment and the second optical compensation layer has been subjected to optical alignment treatment.

9. The polarizing plate with optical compensation layers according to claim 5, wherein: the first optical compensation layer is a layer in which a discotic liquid crystal compound is fixed under a state of being vertically aligned, and the second optical compensation layer is a layer in which molecules of a rod-shaped liquid crystal compound are aligned under a state of being arrayed in a slow axis direction of the second optical compensation layer.

10. The polarizing plate with optical compensation layers according to claim 1, wherein: the number of foreign materials actually present in the first optical compensation layer is 100 foreign materials/m² or more, and the number of display defects in the polarizing plate with optical compensation layers is 10 display defects/m² or less.

11. The polarizing plate with optical compensation layers according to claim 1, having entire thickness of from 20 μm to 100 μm.

12. A polarizing plate with optical compensation layers comprising in this order:
a polarizer;
a first optical compensation layer; and
a second optical compensation layer,
wherein the first optical compensation layer comprises an alignment fixed layer of a liquid crystal compound, shows a refractive index characteristic of nx=nz>ny, and has an in-plane retardation Re(550) of from 220 nm to 320 nm,
wherein the second optical compensation layer comprises an alignment fixed layer of a liquid crystal compound, shows a refractive index characteristic of nx>ny=nz, and has an in-plane retardation Re(550) of from 100 nm to 200 nm,
wherein an angle formed by an absorption axis of the polarizer and a slow axis of the first optical compensation layer is from 10° to 20°, and an angle formed by the absorption axis of the polarizer and a slow axis of the second optical compensation layer is from 70° to 80°,
wherein the first optical compensation layer has been subjected to rubbing treatment and the second optical compensation layer has been subjected to optical alignment treatment, and
wherein the first optical compensation layer contains rubbing debris, the first optical compensation layer has a thickness of 1.5 μm or more, and the first optical compensation layer is free from protruding portion having a height of 0.4 μm or more.

13. The polarizing plate with optical compensation layers according to claim 12, wherein: the number of foreign materials actually present in the first optical compensation layer is 100 foreign materials/m² or more, and the number of display defects in the polarizing plate with optical compensation layers is 10 display defects/m² or less.

14. An image display apparatus, comprising the polarizing plate with optical compensation layers of claim 12.
